(19) United States
(12) Patent Application Publication
(10) Pub. No.: US 2017/0088975 A1
(43) Pub. Date: Mar. 30, 2017

(54) METHOD FOR GROWING NIOBIUM OXYNITRIDE LAYER

(71) Applicant: Panasonic Intellectual Property Management Co., Ltd., Osaka (JP)

(72) Inventors: RYOSUKE KIKUCHI, Osaka (JP); TORU NAKAMURA, Osaka (JP); SATORU TAMURA, Osaka (JP); HIDEAKI MURASE, Osaka (JP); KAZUHITO HATO, Osaka (JP)

(21) Appl. No.: 15/196,119

(22) Filed: Jun. 29, 2016

(30) Foreign Application Priority Data
Sep. 28, 2015 (JP) 2015-189073
Feb. 17, 2016 (JP) 2016-027500

(51) Int. Cl. C30B 25/06; C30B 29/68; C30B 29/16; C25B 1/04; H01G 9/20; C25B 9/06; C23C 14/00; C23C 14/08; C23C 14/34; C30B 29/38; C25B 11/04

(52) U.S. Cl. CPC C30B 25/06; C30B 29/38; C30B 29/68; C30B 29/16; C25B 1/04; C25B 11/0405; C25B 11/0415; C25B 11/0447; C25B 9/06; C23C 14/0036; C23C 14/083; C23C 14/3414; H01G 9/2031

(57) ABSTRACT

To provide a method for growing a niobium oxynitride having small carrier density, the present invention is a method for growing a niobium oxynitride layer, the method comprising: (a) growing a first niobium oxynitride film on a crystalline titanium oxide substrate, while a temperature of the crystalline titanium oxide substrate is maintained at not less than 600 Celsius degrees and not more than 750 Celsius degrees; and (b) growing a second nitride oxynitride film on the first niobium oxynitride film, while the temperature of the crystalline titanium oxide substrate is maintained at not less than 350 Celsius degrees, after the step (a), wherein the niobium oxynitride layer comprises the first niobium oxynitride film and the second niobium oxynitride film.

### BACKGROUND

1. Technical Field

The present invention relates to a method for growing a niobium oxynitride layer.

2. Description of the Related Art

WO2013/035291 discloses a method for growing an NbON thin film by a sputtering method on a quartz substrate maintained at a temperature of 700 degrees Celsius in the paragraph 0074. Furthermore, WO2013/035291 discloses that a plate-like semiconductor photoelectrode comprising the NbON thin film is irradiated with light to generate hydrogen.

### SUMMARY

An object of the present invention is to provide a method for growing a niobium oxynitride layer having low carrier density.

The present invention is a method for growing a niobium oxynitride layer, the method comprising:

(a) growing a first niobium oxynitride film on a crystalline titanium oxide substrate, while a temperature of the crystalline titanium oxide substrate is maintained at not less than 600 degrees Celsius and not more than 750 degrees Celsius; and

(b) growing a second niobium oxynitride film on the first niobium oxynitride film, while the temperature of the crystalline titanium oxide substrate is maintained at not less than 350 degrees Celsius, after the step (a), wherein

the niobium oxynitride layer comprises the first niobium oxynitride film and the second niobium oxynitride film.

The present invention provides a method for growing a niobium oxynitride layer having low carrier density.

### BRIEF DESCRIPTION OF THE DRAWINGS

FIG. 1 shows a cross-sectional view of a semiconductor photoelectrode 100 according to an embodiment of the present invention.

FIG. 2 shows a result of an X-ray diffraction analysis of the semiconductor photoelectrode 100 according to the inventive example 1.

FIG. 3 shows a cross-sectional SEM image of the semiconductor photoelectrode 100 according to the inventive example 1.

FIG. 4 shows a result of the X-ray diffraction analysis of the semiconductor photoelectrode 100 according to the inventive example 2.

FIG. 5 shows a result of the X-ray diffraction analysis of the semiconductor photoelectrode 100 according to the inventive example 3.

FIG. 6 shows a result of the X-ray diffraction analysis of the semiconductor photoelectrode 100 according to the inventive example 4.

FIG. 7 shows a result of the X-ray diffraction analysis of the semiconductor photoelectrode 100 according to the inventive example 5.

FIG. 8 shows a result of the X-ray diffraction analysis of the semiconductor photoelectrode according to the comparative example 1.

FIG. 9 shows a cross-sectional SEM image of the semiconductor photoelectrode according to the comparative example 1.

FIG. 10 shows a cross-sectional view of a hydrogen generation device according to the embodiment.

FIG. 11 shows a cross-sectional view of the semiconductor photoelectrode 100 according to a first variation.

### DETAILED DESCRIPTION OF THE EMBODIMENT

Hereinafter, the embodiment of the present invention will be described in detail with reference to the drawings.

### Embodiment

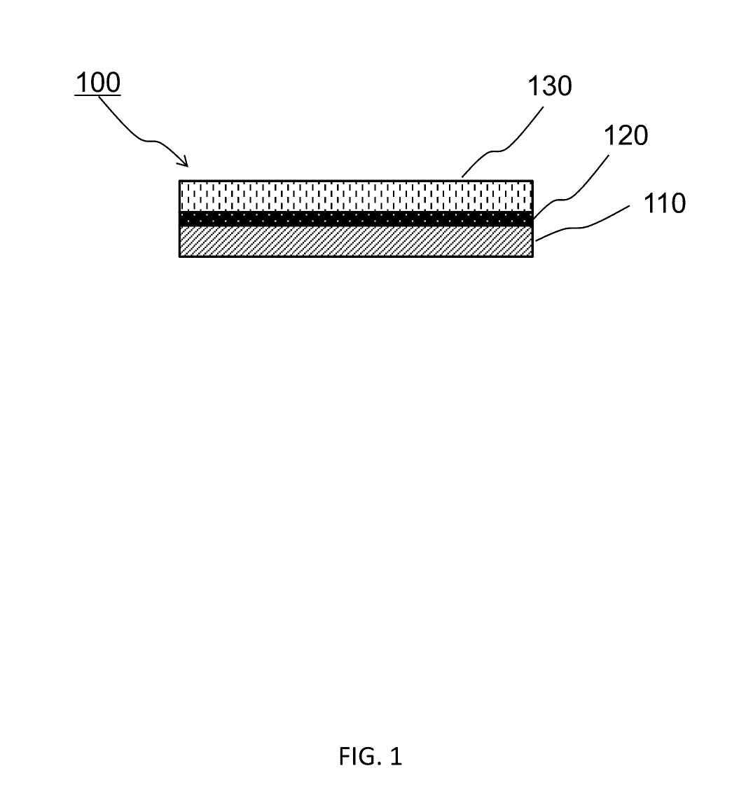

FIG. 1 shows a cross-sectional view of the semiconductor photoelectrode 100 according to the embodiment. The semiconductor photoelectrode 100 comprises a crystalline titanium oxide substrate 110 (hereinafter, referred to as “substrate 110”), a first niobium oxynitride film 120, and a second niobium oxynitride film 130. The substrate 110 may include another layer, as far as the surface of the substrate 110 is formed of crystalline titanium oxide. Desirably, the substrate 110 is monocrystalline.

The first niobium oxynitride film 120 is formed on the surface of the substrate 110. Desirably, the first niobium oxynitride film 120 has a principal surface of a (100) plane. The second niobium oxynitride film 130 is formed on the surface of the first niobium oxynitride film 120. Desirably, the second niobium oxynitride film 130 also has a principal surface of a (100) plane.

A niobium oxynitride layer comprises the first niobium oxynitride film 120 and the second niobium oxynitride film 130. Desirably, the niobium oxynitride layer consists of the first niobium oxynitride film 120 and the second niobium oxynitride film 130. As demonstrated in the inventive examples which will be described later, the first niobium oxynitride film 120 is not distinguishable from the second niobium oxynitride film 130. Therefore, in the present invention, it seems that one niobium oxynitride layer is formed on the substrate 110.

Niobium oxynitride is represented by the chemical formula NbON. Niobium oxynitride is one of n-type semiconductors. Both of the first niobium oxynitride film 120 and the second niobium oxynitride film 130 are formed of niobium oxynitride represented by the chemical formula NbON.

(Manufacturing Method)

Hereinafter, the growth method according to the present invention will be described in more detail.

(Step (a))

First, in the step (a), while the temperature of the substrate 110 is maintained at not less than 600 degrees Celsius and not more than 750 degrees Celsius, the first niobium oxynitride film 120 is grown on the substrate 110. As described above, the substrate 110 is formed of crystalline titanium oxide. It is desirable that the substrate 110 is formed of monocrystalline titanium oxide. Needless to say, titanium oxide is represented by the chemical formula TiO₂. It is desirable that the grown first niobium oxynitride film 120 has a principal surface of a (100) plane.

It is desirable that the substrate 110 has a principal surface of a (101) plane. In other words, it is desirable that the surface of the substrate 110 formed of crystalline titanium oxide is oriented in a [101] direction. It is more desirable that the substrate 110 comprises a crystalline titanium oxide film having a (101) orientation only on the surface thereof.

The term “growth” used in the present specification means growth by an epitaxial method. An example of the epitaxial growth method is a sputtering method, a molecular beam epitaxial method, a pulse laser deposition method, or a metalorganic chemical vapor deposition method. A sputtering method is desirable.

In the sputtering method, a target formed of a niobium oxide represented by the chemical formula Nb₂O₅ is used. Sputtering is conducted in a mixture atmosphere of oxygen and nitrogen. In this way, grown are the first niobium oxynitride film 120 and the second niobium oxynitride film 130 each represented by the chemical formula NbON.

When the substrate 110 has a principal surface of a (101) plane, the first niobium oxynitride film 120 has a principal surface of a (100) plane. It is more desirable that the first niobium oxynitride film 120 has a (100) orientation only.

When the temperature of the substrate 110 is less than 600 degrees Celsius in the step (a), the first niobium oxynitride film 120 fails to have a principal surface of a (100) plane. In other words, in this case, the first niobium oxynitride film 120 may have an orientation plane other than a (100) plane.

The first niobium oxynitride film 120 may have a thickness of not less than 5 nanometers and not more than 30 nanometers.

(Step (b))

The step (b) is conducted after the step (a). In the step (b), while the temperature of the crystalline titanium oxide substrate 110 is maintained at not less than 350 degrees Celsius, the second niobium oxynitride film 130 is grown on the first niobium oxynitride film 120.

Since the second niobium oxynitride film 130 is grown on the first niobium oxynitride film 120, when the substrate 110 has a principal surface of a (101) plane, the second niobium oxynitride film 130 also has a principal surface of a (100) plane. It is more desirable that the second niobium oxynitride film 130 has a (100) orientation only.

When the temperature of the substrate 110 is less than 350 degrees Celsius in the step (b), it is difficult to grow the second niobium oxynitride film 130. In the step (b), the temperature of the substrate 110 may be not more than 500 degrees Celsius.

The second niobium oxynitride film 130 may have a thickness of not less than 70 nanometers and not more than 120 nanometers. Desirably, the second niobium oxynitride film 130 is thicker than the first niobium oxynitride film 120.

The niobium oxynitride layer grown in this way has a low carrier density of less than 1.0×10²⁰ cm⁻³. On the other hand, if the step (b) is not conducted, as demonstrated in the comparative example 1, the obtained niobium oxynitride layer has a high carrier density of not less than 1.0×10²⁰ cm⁻³.

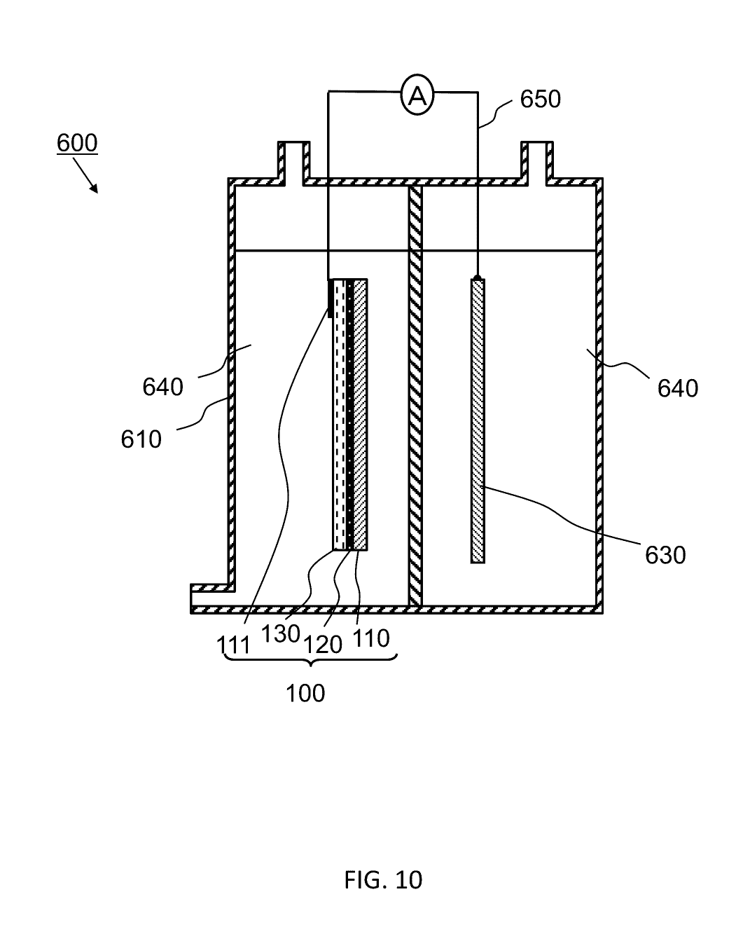

FIG. 10 shows a cross-sectional view of a hydrogen generation device comprising the semiconductor photoelectrode 100 (hereinafter, referred to as “photocatalyst electrode 100”) comprising the first niobium oxynitride film 120 and the second niobium oxynitride film 130. Niobium oxynitride is a photosemiconductor, and may be used as a photocatalyst. The hydrogen generation device shown in FIG. 10 comprises the photocatalyst electrode 100, a counter electrode 630, a liquid 640, and a container 610. As described above, the photocatalyst electrode 100 comprises the substrate 110, the first niobium oxynitride film 120 and the second niobium oxynitride film 130. An ohmic electrode 111 is formed on the second niobium oxynitride film 130, and the counter electrode 630 is electrically connected to the ohmic electrode 111 through a conducting wire 650. For more detail, see United States Patent Pre-Grant Publication No. 2011/0305949, the entire contents of which are incorporated herein by reference.

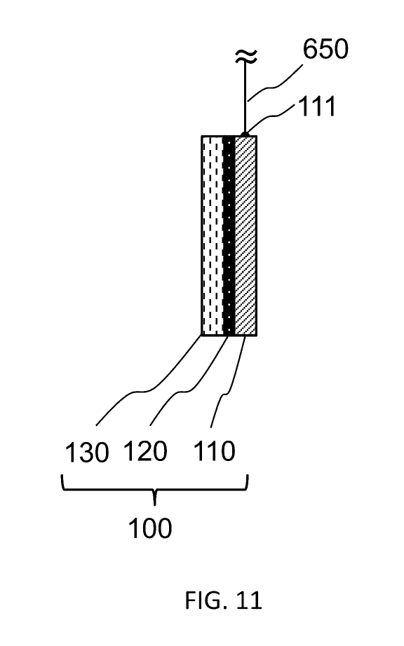

FIG. 11 shows a cross-sectional view of the photocatalyst electrode 100 according to a first variation. In the first variation, a titanium oxide substrate 110 doped with niobium is used. The titanium oxide substrate is doped with niboium to allow the titanium oxide substrate to be electrically conductive. Then, as shown in FIG. 11, an ohmic electrode 111 is formed on the titanium oxide substrate 110 having electrical conductivity. The ohmic electrode 111 is electrically connected to the conducting wire 650.

It is desirable that the counter electrode 630 is formed of a material having a small overvoltage. In particular, an example of the material of the counter electrode 630 is platinum, gold, silver, nickel, ruthenium oxide represented by the chemical formula RuO₂, or iridium oxide represented by the chemical formula IrO₂.

The liquid 640 is water or an electrolyte aqueous solution. The electrolyte aqueous solution is acidic or alkaline. An example of the electrolyte aqueous solution is a sulfuric acid aqueous solution, a sodium sulfate aqueous solution, a sodium carbonate aqueous solution, a phosphate buffer solution, or a borate buffer solution. The liquid 640 may be constantly stored in the container 610 or may be supplied only in use.

The container 610 contains the photocatalyst electrode 100, the counter electrode 630, and the liquid 640. It is desirable that the container 610 is transparent. In particular, it is desirable that at least a part of the container 610 is transparent so that light can travel from the outside of the container 610 to the inside of the container 610.

When a niobium oxynitride layer consisting of the first niobium oxynitride film 120 and the second niobium oxynitride film 130 is irradiated with light, oxygen is generated on the second niobium oxynitride film 130. Light such as sunlight travels through the container 610 and reaches the niobium oxynitride layer. Electrons and holes are generated respectively in the conduction band and valence band of the part of the niobium oxynitride layer in which the light has been absorbed. Since the niobium oxynitride layer is an n-type semiconductor, the holes migrate to the surface of the second niobium oxynitride film 130.

Water is split on the surface of the second niobium oxynitride film 130 as shown in the following reaction formula (1) to generate oxygen. On the other hand, electrons migrate from the niobium oxynitride layer to the counter electrode 630 through the conducting wire 650. Hydrogen is generated as shown in the following reaction formula (2) on the surface of the counter electrode 630.

4h⁺+2H₂O→O₂↑+4H⁺ (1)

(h⁺ represents a hole)

4e⁻+4H⁺→2H₂↑ (2)

There is a depletion layer having a band bending on a solid-liquid interface formed on the surface of the second niobium oxynitride film 130. Theoretically, a depletion layer extends with a decrease of carrier density. Therefore, in a case where carrier density is low, electrons and holes generated in the conduction band and the valence band respectively are easily separated due to the internal electric field of the depletion layer. Since the photocatalyst electrode 100 according to the embodiment has a low carrier density of less than 1.0×10²⁰ cm⁻³, a hydrogen generation device comprising the photocatalyst electrode 100 according to the embodiment has high hydrogen generation efficiency.

### EXAMPLES

Hereinafter, the present invention will be described in more detail with reference to the following examples.

### Inventive Example 1

In the inventive example 1, the semiconductor photoelectrode 100 shown in FIG. 1 was manufactured as below.

First, a first niobium oxynitride film 120 having a thickness of 20 nanometers was grown by a reactive sputtering method on a titanium oxide substrate 110 having a (101) orientation only. In the reactive sputtering method, the temperature of the titanium oxide substrate 110 was maintained at 650 degrees Celsius. The material of the sputtering target was a niobium oxide represented by the chemical formula Nb₂O₅. Sputtering was conducted in a mixture atmosphere of oxygen and nitrogen. The total pressure in the chamber used for the sputtering was 0.5 Pa. The partial pressure of oxygen was 0.017 Pa and the partial pressure of nitrogen was 0.48 Pa. In this way, the first niobium oxynitride film 120 was grown.

Then, while the temperature of the titanium oxide substrate 110 was maintained at 500 degrees Celsius, a second niobium oxynitride film 130 having a thickness of 120 nanometers was grown on the first niobium oxynitride film 120 by a reactive sputtering method. The material of the sputtering target was a niobium oxide represented by the chemical formula Nb₂O₅. Sputtering was conducted in a mixture atmosphere of oxygen and nitrogen. The total pressure in the chamber used for sputtering was 0.5 Pa. The partial pressure of oxygen was 0.011 Pa and the partial pressure of nitrogen was 0.49 Pa. In this way, the second niobium oxynitride film 130 was grown.

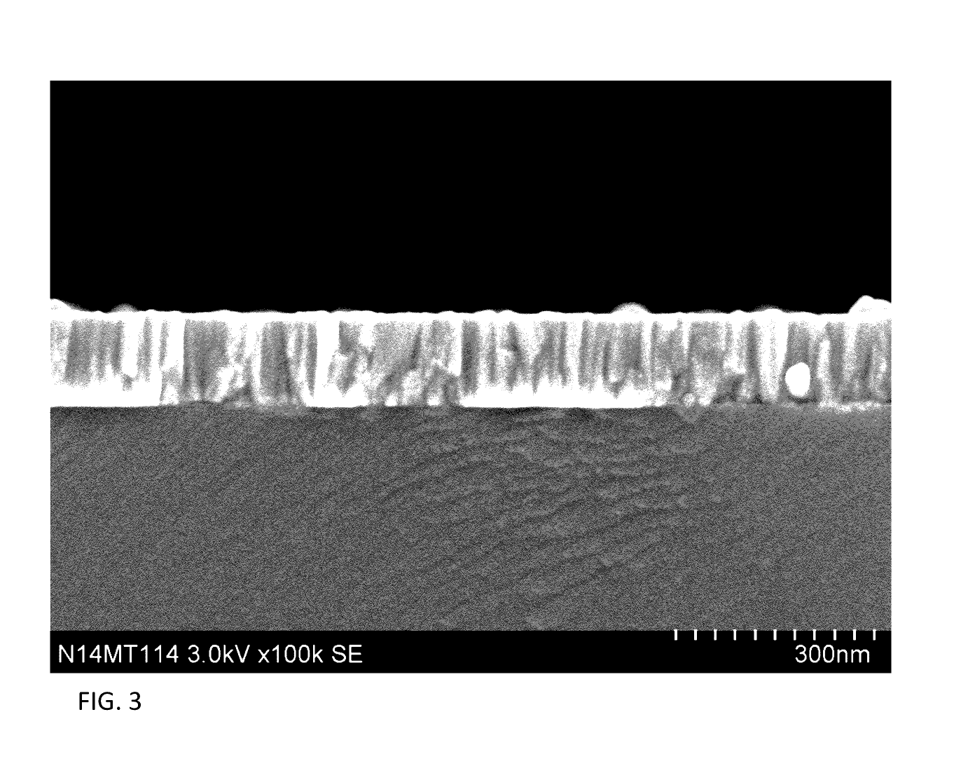

FIG. 3 shows a cross-sectional SEM image of the semiconductor photoelectrode 100 according to the inventive example 1. As is clear from FIG. 3, one niobium oxynitride layer was formed on the substrate 110. In other words, the first niobium oxynitride film 120 is not distinguishable from the second niobium oxynitride film 130. The niobium oxynitride layer is flat and dense. As shown in FIG. 3, neither a void nor a pinhole was formed in the niobium oxynitride layer.

Then, the carrier density of the semiconductor photoelectrode 100 was calculated through the Hall effect measurement based on the Van der Pauw method. As a result, the niobium oxynitride layer according to the inventive example 1 had a carrier density of 1.0×10¹⁸ cm⁻³.

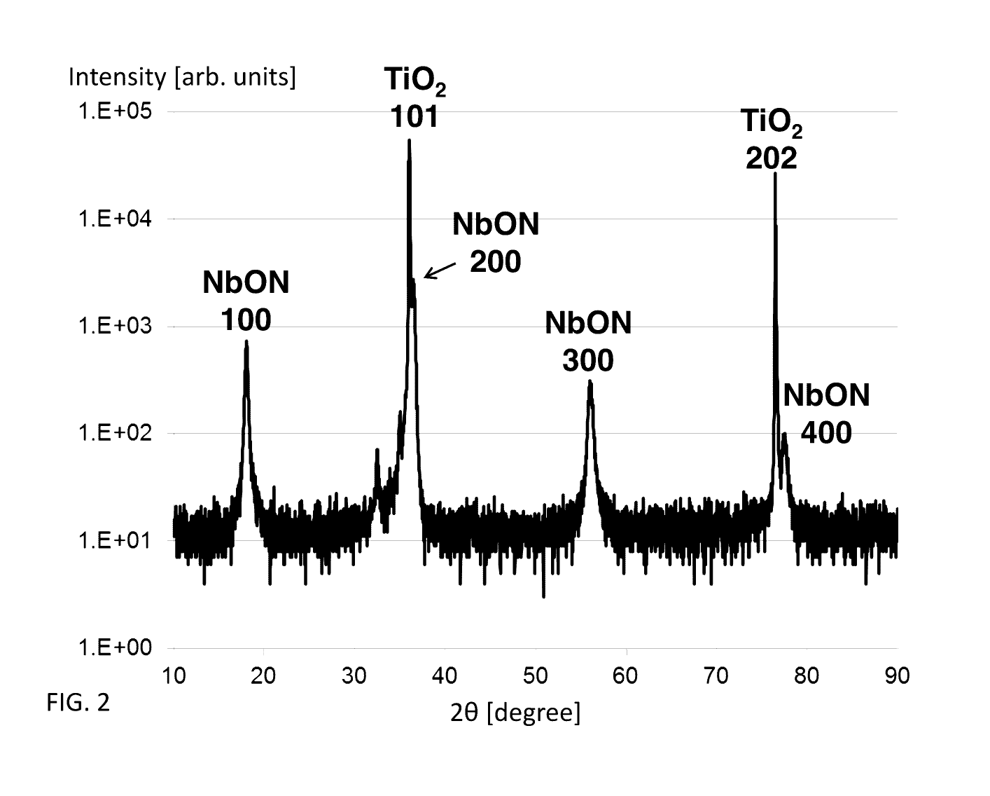

The semiconductor photoelectrode 100 was subjected to an X-ray diffraction analysis. FIG. 2 shows the result. As is clear from FIG. 2, six peaks were observed. Among them, two peaks are derived from a (101) plane and a (202) plane of TiO₂. Four peaks are derived from a (100) plane, a (200) plane, a (300) plane, and a (400) plane of NbON. As just described, only peaks of (h00) planes of NbON were observed. This means that a niobium oxynitride layer having a (100) orientation only was formed on the crystalline titanium oxide substrate 110 having a (101) orientation.

### Inventive Example 2

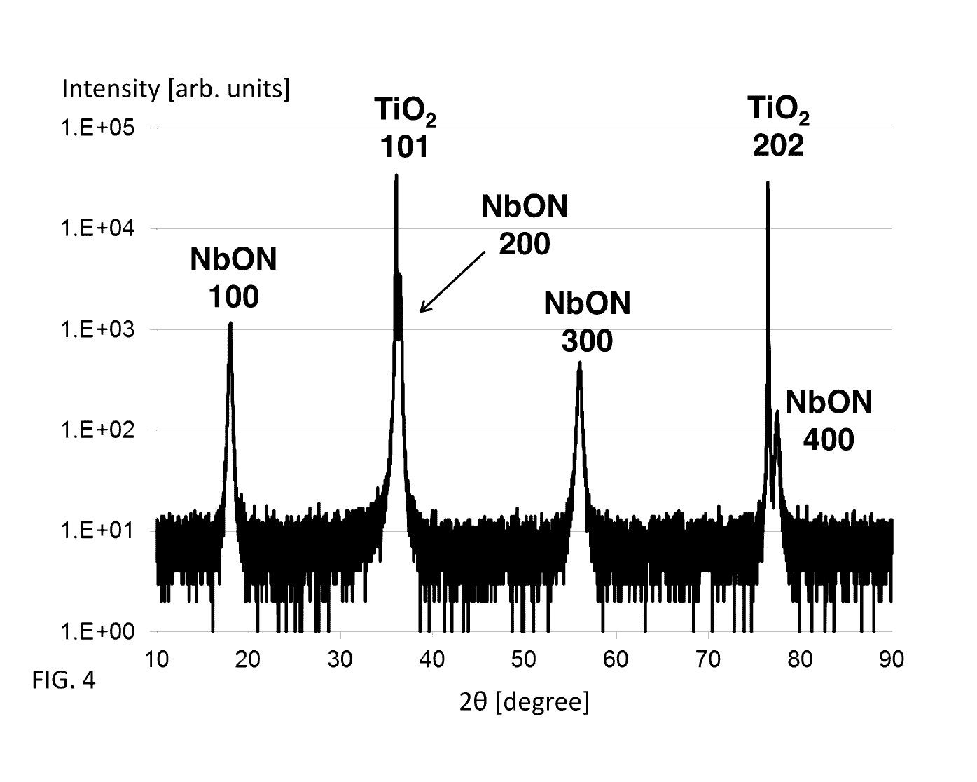

In the inventive example 2, an experiment similar to the inventive example 1 was conducted, except that the first niobium oxynitride film 120 was grown while the temperature of the titanium oxide substrate 110 was maintained at 600 degrees Celsius and that the second niobium oxynitride film 130 had a thickness of 70 nanometers. FIG. 4 shows the result of the X-ray diffraction analysis in the inventive example 2. The niobium oxynitride layer according to the inventive example 2 had a carrier density of 3.1×10¹⁹ cm⁻³.

### Inventive Example 3

In the inventive example 3, an experiment similar to the inventive example 1 was conducted except for the following matters (I) to (III).

(I) The first niobium oxynitride film 120 was grown while the temperature of the titanium oxide substrate 110 was maintained at 750 degrees Celsius.

(II) The second niobium oxynitride film 130 had a thickness of 70 nanometers.

(III) During the sputtering for growing the first niobium oxynitride film 120, the partial pressure of oxygen was 0.023 Pa and the partial pressure of nitrogen was 0.48 Pa.

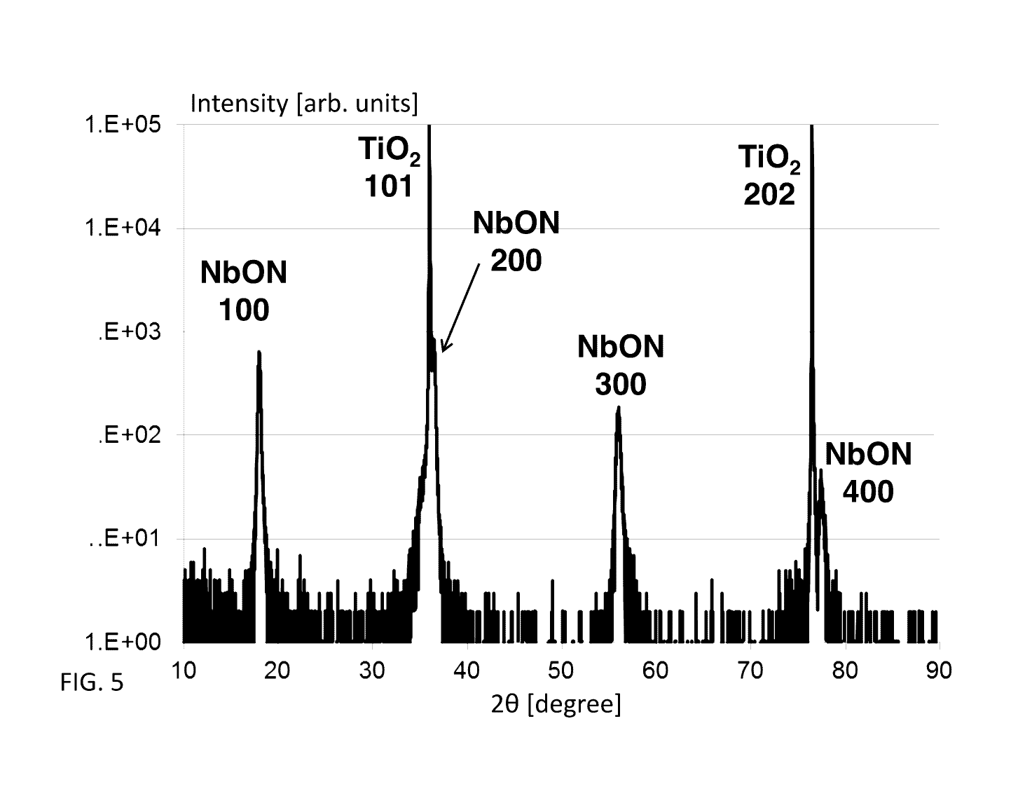

FIG. 5 shows the result of the X-ray diffraction analysis in the inventive example 3. The niobium oxynitride layer according to the inventive example 3 had a carrier density of 4.2×10¹⁹ cm⁻³.

### Inventive Example 4

In the inventive example 4, an experiment similar to the inventive example 1 was conducted except for the following matters (I) to (IV).

(I) The first niobium oxynitride film 120 was grown while the temperature of the titanium oxide substrate 110 was maintained at 600 degrees Celsius.

(II) The second niobium oxynitride film 130 had a thickness of 70 nanometers.

(III) The second niobium oxynitride film 130 was grown while the temperature of the titanium oxide substrate 110 was maintained at 350 degrees Celsius.

(IV) During the sputtering for growing the second niobium oxynitride film 130, the partial pressure of oxygen was 0.0074 Pa and the partial pressure of nitrogen was 0.49 Pa.

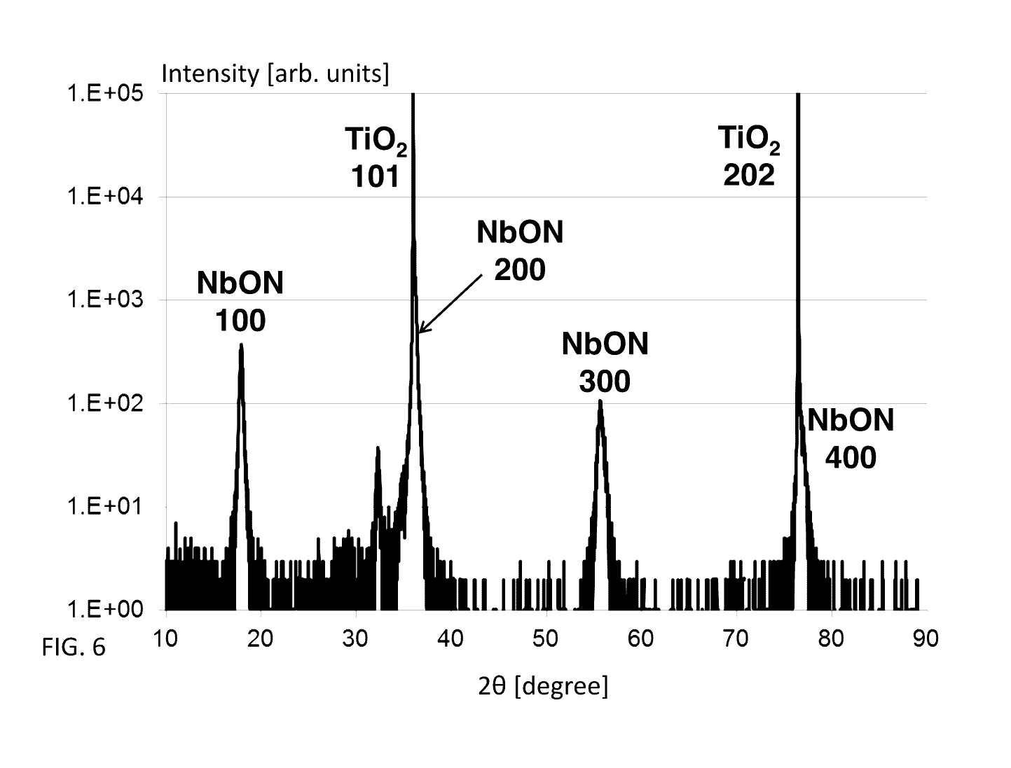

FIG. 6 shows the result of the X-ray diffraction analysis in the inventive example 4. The niobium oxynitride layer according to the inventive example 4 had a carrier density of 3.0×10¹⁹ cm⁻³.

### Inventive Example 5

In the inventive example 5, an experiment similar to the inventive example 1 was conducted except for the following matters (I) to (V).

(I) The first niobium oxynitride film 120 was grown while the temperature of the titanium oxide substrate 110 was maintained at 750 degrees Celsius.

(II) During the sputtering for growing the first niobium oxynitride film 120, the partial pressure of oxygen was 0.023 Pa and the partial pressure of nitrogen was 0.48 Pa.

(III) The second niobium oxynitride film 130 had a thickness of 70 nanometers.

(IV) The second niobium oxynitride film 130 was grown while the temperature of the titanium oxide substrate 110 was maintained at 350 degrees Celsius.

(V) During the sputtering for growing the second niobium oxynitride film 130, the partial pressure of oxygen was 0.0074 Pa and the partial pressure of nitrogen was 0.49 Pa.

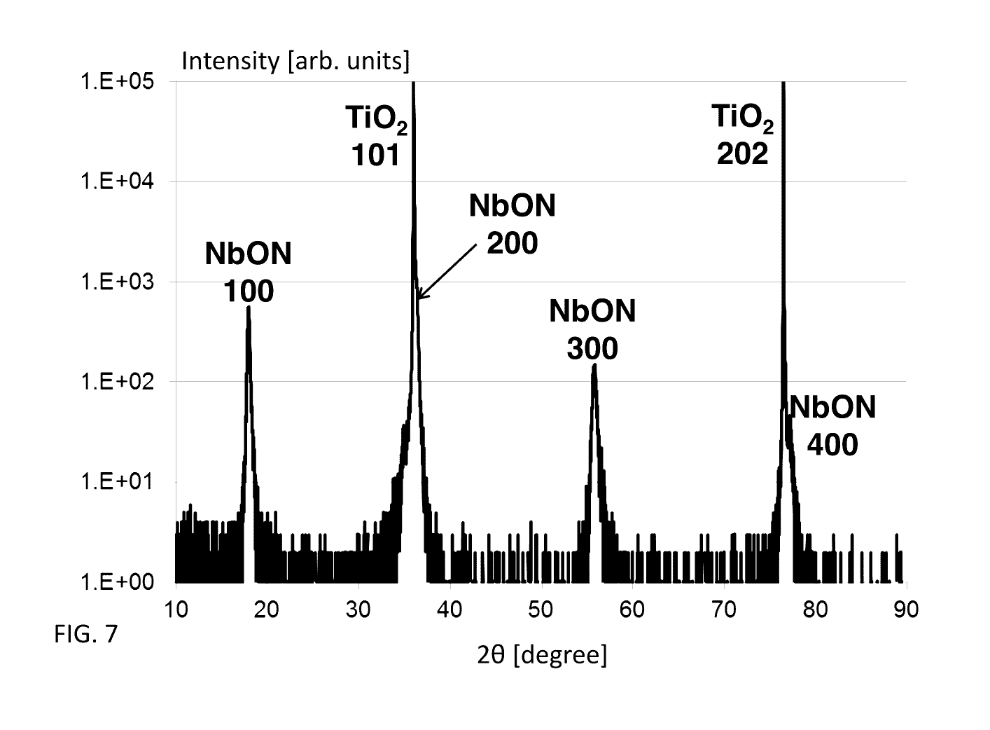

FIG. 7 shows the result of the X-ray diffraction analysis in the inventive example 5. The niobium oxynitride layer according to the inventive example 5 had a carrier density of 2.8×10¹⁹ cm⁻³.

### Comparative Example 1

In the comparative example 1, an experiment similar to the inventive example 1 was conducted except for the following matters (I) to (IV).

(I) The first niobium oxynitride film 120 was grown while the temperature of the titanium oxide substrate 110 was maintained at 650 degrees Celsius.

(II) During the sputtering for growing the first niobium oxynitride film 120, the partial pressure of oxygen was 0.085 Pa and the partial pressure of nitrogen was 0.49 Pa.

(III) The first niobium oxynitride film 120 had a thickness of 70 nanometers.

(IV) The second niobium oxynitride film 130 was not grown.

In other words, in the comparative example 1, a niobium oxynitride layer having a thickness of 70 nanometers was formed on the TiO₂ substrate having a (101) orientation by a reactive sputtering method. In the reactive sputtering method, the TiO₂ substrate was maintained at 650 degrees Celsius. The total pressure in the chamber used for the sputtering was 0.5 Pa. The partial pressure of oxygen was 0.085 Pa and the partial pressure of nitrogen was 0.49 Pa.

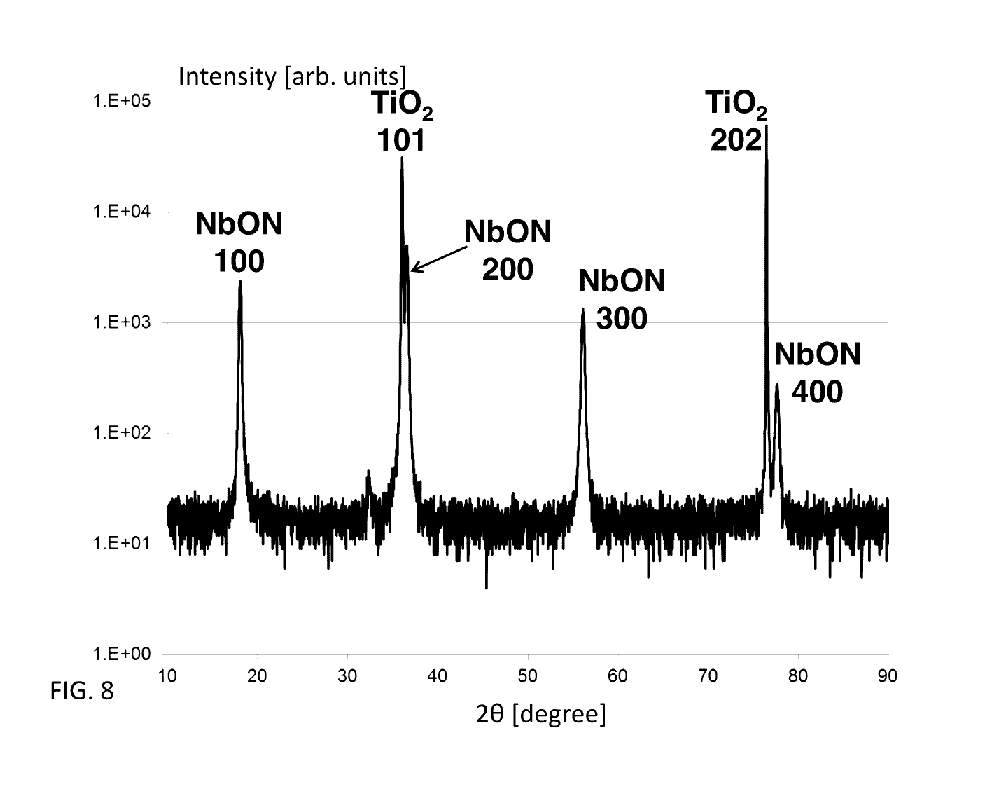

FIG. 8 shows the result of the X-ray diffraction analysis in the comparative example 1. Similarly to the case of FIG. 2, it was observed that the niobium oxynitride layer according to the comparative example 1 had peaks of (h00) planes of NbON only. This means that a niobium oxynitride layer having a (100) plane only was formed on the crystalline titanium oxide substrate 110 having a (101) orientation.

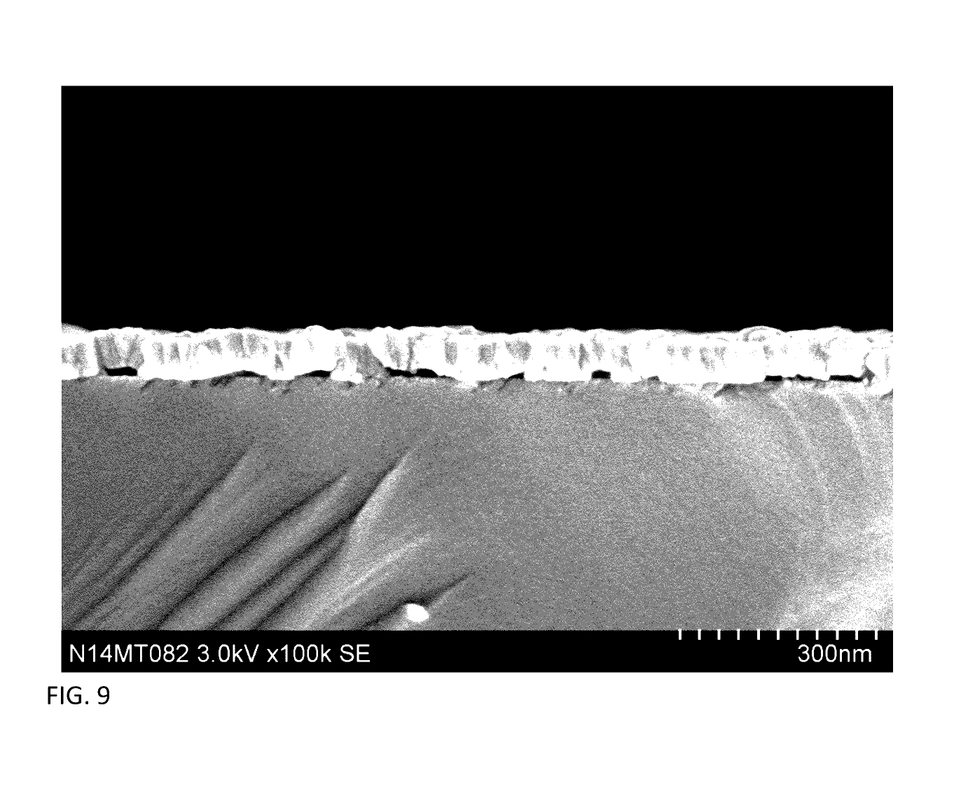

FIG. 9 shows a cross-sectional SEM image of the semiconductor photoelectrode 100 according to the comparative example 1. As is clear from FIG. 9, the niobium oxynitride layer according to the comparative example 1 was uneven and deformed. Furthermore, in the niobium oxynitride layer according to the comparative example 1, voids were formed between the TiO₂ substrate and the niobium oxynitride layer. The niobium oxynitride layer according to the comparative example 1 had a carrier density of approximately 1.0×10²⁰ cm⁻³.

The following Table 1-Table 2 show the results of the inventive examples 1-5 and the comparative example 1. In Table 1 and Table 2, First film and Second film mean the first niobium oxynitride film 120 and the second niobium oxynitride film 130, respectively.

TABLE 1

| | Inventive | Inventive | Inventive | Inventive |
|---|---|---|---|---|
| | example 1 | example 2 | example 3 | example 4 |
| Growth temperature of | 650 | 600 | 750 | 600 |
| First film 120 | | | | |
| (degrees Celsius) | | | | |
| Thickness of First film | 20 | 20 | 20 | 20 |
| 120 (nanometers) | | | | |
| Growth temperature of | 500 | 500 | 500 | 350 |
| Second film 130 | | | | |
| (degrees Celsius) | | | | |
| Thickness of Second film | 120 | 70 | 70 | 70 |
| 130 (nanometers) | | | | |
| Orientation | (100) only | (100) only | (100) only | (100) only |
| Flatness characteristics | Good | Good | Good | Good |
| Carrier density (cm⁻³) | 1.0 × 10¹⁸ | 3.1 × 10¹⁹ | 4.2 × 10¹⁹ | 3.0 × 10¹⁹ |

TABLE 2

| | Inventive | Comparative |
|---|---|---|
| | example 5 | example 1 |
| Growth temperature of First film | 750 | 650 |
| 120 (degrees Celsius) | | |
| Thickness of First film 120 | 20 | 70 |
| (nanometers) | | |
| Growth temperature of Second | 350 | (Not grown) |
| film 130 (degrees Celsius) | | |
| Thickness of Second film 130 | 70 | (Not grown) |
| (nanometers) | | |
| Orientation | (100) only | (100) only |
| Flatness characteristics | Good | Poor |
| Carrier density (cm⁻³) | 2.8 × 10¹⁹ | 1.0 × 10²⁰ |

As is clear from Table 1 and Table 2, when the following requirements (I) and (II) are satisfied, the obtained niobium oxynitride layer has a low carrier density of less than 1.0×10²⁰ cm⁻³.

(I) the first niobium oxynitride film 120 is grown on the crystalline titanium oxide substrate 110 while the temperature of the crystalline titanium oxide substrate 110 is maintained at not less than 600 degrees Celsius and not more than 750 degrees Celsius, and

(II) the second niobium oxynitride film 130 is grown on the first niobium oxynitride film 120 while the temperature of the crystalline titanium oxide substrate 110 is maintained at not less than 350 degrees Celsius (desirably, maintained at not more than 500 degrees Celsius).

As is clear from the comparative example 1, even when the niobium oxynitride layer has a single orientation (i.e., a (100) orientation only), the niobium oxynitride layer does not always have low carrier density.

### INDUSTRIAL APPLICABILITY

The niobium oxynitride layer according to the present invention can be used for a photosemiconductor irradiated with light to generate hydrogen.

### REFERENTIAL SIGNS LIST

110 Crystalline titanium oxide substrate
120 First niobium oxynitride film
130 Second niobium oxynitride film

1. A method for growing a niobium oxynitride layer, the method comprising:
(a) growing a first niobium oxynitride film on a crystalline titanium oxide substrate, while a temperature of the crystalline titanium oxide substrate is maintained at not less than 600 degrees Celsius and not more than 750 degrees Celsius; and
(b) growing a second niobium oxynitride film on the first niobium oxynitride film, while the temperature of the crystalline titanium oxide substrate is maintained at not less than 350 degrees Celsius, after the step (a), wherein
the niobium oxynitride layer comprises the first niobium oxynitride film and the second niobium oxynitride film.

2. The method according to claim 1, wherein
the substrate has a principal surface of a (101) plane.

3. The method according to claim 1, wherein
both of the first niobium oxynitride film and the second niobium oxynitride film have a principal surface of a (100) plane.

4. The method according to claim 1, wherein
the second niobium oxynitride film is thicker than the first niobium oxynitride film.

5. The method according to claim 1, wherein
the first niobium oxynitride film has a thickness of not less than 5 nanometers and not more than 30 nanometers.

6. The method according to claim 1, wherein
the niobium oxynitride layer has a carrier density of less than 1.0×10²⁰ cm⁻³.

7. The method according to claim 1, wherein
the first niobium oxynitride film is grown by a sputtering method.

8. The method according to claim 7, wherein
a sputtering target used in the sputtering method is formed of a niobium oxide represented by the chemical formula Nb₂O₅; and
the first niobium oxynitride film is grown in a mixture atmosphere of oxygen and nitrogen.

9. The method according to claim 1, wherein
the second niobium oxynitride film is grown by a sputtering method.

10. The method according to claim 9, wherein
a sputtering target used in the sputtering method is formed of a niobium oxide represented by the chemical formula Nb₂O₅; and
the second niobium oxynitride film is grown in a mixture atmosphere of oxygen and nitrogen.

11. The method according to claim 1, wherein
in the step (b), the temperature of the crystalline titanium oxide substrate is maintained at not more than 500 degrees Celsius.

12. A niobium oxynitride layer, wherein
the niobium oxynitride layer has a carrier density of less than 1.0×10²⁰ cm⁻³.

13. The niobium oxynitride layer according to claim 12, wherein the niobium oxynitride layer is a photosemiconductor layer.

14. A semiconductor photoelectrode comprising:
the photosemiconductor layer according to claim 13; and
a substrate which supports the photosemiconductor layer.

15. The semiconductor photoelectrode according to claim 14, wherein the substrate is formed of crystalline titanium oxide.

16. The niobium oxynitride layer according to claim 12, wherein the niobium oxynitride layer is a photocatalyst layer.

17. A photocatalyst electrode comprising:
the photocatalyst layer according to claim 16; and
a substrate which supports the photocatalyst layer.

18. The photocatalyst electrode according to claim 17, wherein the substrate is formed of crystalline titanium oxide.

19. A hydrogen generation device, comprising:
the photocatalyst electrode according to claim 17;
a counter electrode electrically connected to the photocatalyst electrode;
a liquid in contact with the niobium oxynitride layer and the counter electrode; and
a container containing the photocatalyst electrode, the counter electrode, and the liquid, wherein
the liquid is water or an electrolyte aqueous solution; and
hydrogen is generated on a surface of the counter electrode when the niobium oxynitride layer is irradiated with light.

20. A method for generating hydrogen, comprising:
(a) preparing a hydrogen generation device, comprising:
the photocatalyst electrode according to claim 17;
a counter electrode electrically connected to the photocatalyst electrode;
a liquid in contact with the niobium oxynitride layer and the counter electrode; and
a container containing the photocatalyst electrode, the counter electrode, and the liquid, wherein
the liquid is water or an electrolyte aqueous solution; and
(b) irradiating the niobium oxynitride layer with light to generate hydrogen on a surface of the counter electrode.
